(19) United States
(12) Patent Application Publication
(10) Pub. No.: US 2015/0357089 A1
(43) Pub. Date: Dec. 10, 2015

(54) METHOD OF PERSISTENT CURRENT MODE SPLICING OF 2G ReBCO HIGH TEMPERATURE SUPERCONDUCTORS USING SOLID STATE PRESSURIZED ATOMS DIFFUSION BY DIRECT FACE-TO-FACE CONTACT OF HIGH TEMPERATURE SUPERCONDUCTING LAYERS AND RECOVERING SUPERCONDUCTIVITY BY OXYGENATION ANNEALING

(71) Applicant: K. JOINS. INC., Seoul (KR)

(72) Inventors: Young-Kun OH, Seoul (KR); Hee-Sung ANN, Daejeon (KR); Myung-Whon LEE, Seoul (KR)

(73) Assignee: K. JOINS. INC., Seoul (KR)

(21) Appl. No.: 14/170,858

(22) Filed: Feb. 3, 2014

(30) Foreign Application Priority Data
Mar. 29, 2013 (KR) 10-2013-0034863

(51) Int. Cl. H01B 12/06; H01R 43/16; H01R 4/02; H01L 39/12; H01L 39/24

(52) U.S. Cl. CPC H01B 12/06; H01L 39/125; H01L 39/24; H01R 4/02; H01R 43/16

(57) ABSTRACT

Disclosed is a method of splicing ReBCO high temperature superconductors (HTSs), which ensures excellent superconductivity after splicing. The method of splicing 2G ReBCO HTSs allows a superconductors-spliced assembly to exhibit excellent superconductivity by direct contact of high temperature superconducting layers of two strands of 2G ReBCO HTSs and solid state atoms diffusion pressurized splicing there between at a ReBCO below peritectic reaction temperature in a vacuum, and enables loss of superconductivity caused by loss of oxygen due to transport and out-diffusion of oxygen to atoms during splicing to be recovered through oxygenation annealing.

### CROSS-REFERENCE TO RELATED APPLICATION

This application claims priority to Korean Patent Application No. 10-2013-0034863 filed on Mar. 29, 2013, and all the benefits accruing therefrom under 35 U.S.C. §119, the contents of which is incorporated by reference in its entirety.

### BACKGROUND

1. Technical Field

The present invention relates to a method of splicing second generation high temperature superconductors (2G HTSs) including ReBCO (ReBa₂Cu₃O₇₋ₓ, wherein Re is a rare-earth material, and x ranges from 0≦x≦0.6) to each other and recovering superconductivity by oxygenation annealing. More particularly, the present invention relates to a method of splicing 2G ReBCO HTSs to each other, which ensures excellent superconductivity by direct contact and splicing of high temperature superconducting layers of two strands of 2G ReBCO HTSs and solid state atoms diffusion thereof through pressurization, and which allows lost superconductivity due to diffusion of oxygen atoms during splicing to be recovered through oxygenation annealing.

2. Description of the Related Art

Generally, splicing of 2G ReBCO HTS coated conductor (CC) is required in the following cases of magnet manufacturing.

First, short superconductors are spliced for use as a long superconductor for coiling. Second, when connecting superconductor coils, it is necessary to connect superconductor magnet coils to each other. Third, in parallel connection of superconductor permanent current switches for use in permanent current mode (PCM) operation, there is a need to splice a superconductor magnet coil and a superconductor permanent current switch.

Particularly, for superconductor-based devices designed to operate based on PCM, it is necessary to connect superconductors to function as a single superconductor having perfect continuity and uniformity in physical, chemical, and mechanical terms. Thus, the superconductors must be operated without any loss of superconductivity after completion of all winding operations.

For example, such splicing between superconductors is performed for superconductor magnets and superconductor-based devices, such as NMR (Nuclear Magnetic Resonance), MRI (Magnetic Resonance Imaging), SMES (Superconducting Magnet Energy Storage), MAGLEV (MAGnetic LEVitation) systems, and the like.

However, since a spliced zone between superconductors generally has inferior characteristics to non-spliced zones in various regards, critical current (Ic) significantly depends on the spliced zone quality between the superconductors during operation based on PCM.

Thus, improvement of Ic characteristics of the spliced zone between the superconductors is essential in manufacturing of a PCM type superconductor device. However, unlike low temperature superconductors (LTSs), HTSs are formed of ceramic materials, thereby making it very difficult to maintain superconductivity with perfect continuity and uniformity after splicing.

FIG. 1 is a view of a typical 2G ReBCO HTS CC.

Referring to FIG. 1, a typical 2G ReBCO HTS 100 is comprised of a high temperature superconductor material, such as ReBCO(ReBa₂Cu₃O₇₋ₓ, where Re is a rare-earth material, and x ranges from 0≦x≦0.6), and has a laminated tape structure.

The 2G ReBCO HTS 100 generally includes a Cu Stabilizer 110, a Ag overlayer 120, a substrate 130, a buffer layers 140, a high temperature ReBCO superconducting layer 150, a Ag overlayer 120, and a Cu Stabilizer 110 from the bottom, as shown in FIG. 1(a), or a Ag overlayer 120, a substrate 130, a buffer layers 140, a high temperature ReBCO superconducting layer 150, a Ag overlayer 120 from the bottom, as shown in FIG. 1(b).

FIG. 2 schematically shows typical splicing methods of 2G ReBCO HTSs.

FIG. 2 (a) shows a lap joint splicing method in which 2G ReBCO HTSs 100 are directly spliced to each other. On the other hand, FIG. 2 (b) shows a bridge joint splicing method (an overlap joint with butt type arrangement) in which 2G ReBCO HTSs 100 are spliced via a third 2G ReBCO HTS piece 200.

Referring to FIG. 2, generally, a solder 210 or other normal conductive layer is filled between surfaces A of the superconductors to splice the 2G ReBCO HTSs.

However, in the superconductors spliced to each other in this manner, electric current inevitably passes through normal conductive (not superconductive) materials such as the solder or filler 210 and a 2G HTSs 100, which resulted in high resistance, thereby making it difficult to maintain superconductivity of 2G ReBCO HTSs. In the soldering method, a spliced zone can have a very high resistance, ranging from about 20˜2800 nΩ according to superconductor type and splicing arrangement.

### BRIEF SUMMARY

An aspect of the present invention is to provide a solid state splicing method of 2G ReBCO HTSs, in which, with stabilizing layers and/or overlayers on top of the 2G ReBCO superconducting layer removed from the two strands of 2G ReBCO HTSs through chemical wet etching or plasma dry etching, surfaces of the two high temperature superconducting layers are brought into direct contact with each other and are heated in a splicing furnace under vacuum for solid state atoms diffusion at an interface between high temperature superconducting layers, and pressure is applied to the superconductors to improve face-to-face contact between the two superconducting layers and atoms inter-diffusion, thereby splicing the two strands of 2G ReBCO HTSs to each other.

Another aspect of the present invention is to provide a method of splicing 2G ReBCO HTSs, which allows the 2G ReBCO HTSs to maintain superconductivity through oxygen supplied into a splicing furnace, with the 2G ReBCO HTSs reheated to a suitable temperature, by accounting for superconductivity loss of the 2G ReBCO HTSs due to loss of oxygen during splicing.

In accordance with one aspect of the present invention, a method of splicing 2G ReBCO HTSs includes: (a) preparing, as splicing targets, two strands of 2G ReBCO HTSs each including a ReBCO high temperature superconducting layer (ReBa₂Cu₃O₇₋ₓ, wherein Re is a rare-earth material, and x ranges from 0≦x≦0.6) and other layers; (b) drilling holes in a splicing portion of each of the 2G ReBCO HTSs; (c) etching the splicing portion of each of the 2G ReBCO HTSs to remove the Copper (Cu) and/or Silver (Ag) layer from and expose the ReBCO high temperature superconducting layers at the splicing portion; (d) loading the 2G ReBCO HTSs into a splicing furnace, and arranging the 2G ReBCO HTSs such that the exposed surfaces of the two 2G ReBCO HTSs directly abut, or such that the two exposed surfaces of the 2G ReBCO high temperature superconducting layers directly abut an exposed surface of a 2G ReBCO high temperature superconducting layer of a third 2G ReB CO HTS; (e) performing solid state pressurized splicing of the Copper (Cu) stabilizing layer and/or Silver (Ag) overlayers at both ends of the exposed surfaces of the ReBCO high temperature superconducting layers to increase the overall 2G HTSs bonding strength at atmospheric pressure in the splicing furnace; (f) splicing the exposed surfaces of the ReBCO high temperature superconducting layers of the 2G ReBCO HTSs by solid state atoms diffusion with pressure by evacuating the splicing furnace and heating the splicing furnace to below ReBCO peritectic reaction temperature; (g) annealing a spliced zone between the 2G ReBCO HTSs under high rich pure oxygen atmosphere to supply oxygen to the ReBCO high temperature superconducting layer in each of the 2G ReBCO HTSs; (h) coating the spliced zone between the 2G ReBCO HTSs with silver (Ag) so as to prevent quenching by bypassing over-current at the spliced zone; and (i) reinforcing the silver (Ag)-coated spliced zone between the 2G ReBCO HTSs with a solder or epoxy.

In the splicing method of 2G HTSs according to the present invention, with the surfaces of the 2G ReBCO HTSs directly contacting each other, that is, absent solders or fillers, atoms diffusion pressurized splicing of the 2G ReBCO HTSs is performed in solid state, whereby a sufficiently long 2G HTS capable of being used for operation in a persistent current mode (PCM) can be fabricated substantially without resistance in a spliced zone, as compared with conventional normal splicing.

Particularly, in the splicing method of 2G HTSs according to the present invention, the 2G HTSs are subjected to hole-drilling before splicing, thereby providing an oxygen in-diffusion path towards the ReBCO superconducting layers during oxygenation annealing for replenishment of lost oxygen after splicing. As a result, it is possible to reduce annealing duration for replenishment of oxygen, and to provide excellent superconductivity after splicing the 2G HTSs.

### BRIEF DESCRIPTION OF THE DRAWINGS

The above and other aspects, features, and advantages of the present invention will become apparent from the detailed description of the following embodiments in conjunction with the accompanying drawings, in which:

FIG. 1 is a view of a general 2G ReBCO HTS structure;

FIG. 2 schematically shows examples of a typical method of splicing 2G ReBCO HTSs by soldering;

FIG. 3 schematically shows examples of a typical method of splicing 2G ReBCO HTSs by this invention;

FIG. 4 is a schematic flow chart showing a method of splicing ReBCO HTSs via solid state atoms diffusion by pressurized splicing under vacuum condition and recovering superconductivity by oxygenation annealing according to one embodiment of the present invention;

FIG. 5 shows examples of a hole-drilling process of a splicing portion between 2G ReBCO HTSs described below;

FIG. 6 is a view of a 2G ReBCO HTS, from which a stabilizing layer and/or overlayer is removed, after hole-drilling;

FIG. 7 shows one example of lap joint splicing, in which 2G ReBCO HTSs are spliced to each other by lap type arrangement after hole drilling the 2G ReBCO HTSs and removing stabilizing layers and/or overlayers from;

FIG. 8 shows one example of bridge joint, in which two 2G ReBCO HTSs are spliced by overlapping a third 2G ReBCO HTS piece. i.e. a third ReBCO HTS piece subjected to hole-drilling and removal of a stabilizing layers and/or overlayers is placed on two 2G ReBCO HTSs subjected to hole-drilling and removal of a stabilizing layers and/or overlayers disposed in butt arrangement;

FIG. 9 shows a vertical hole pitch (dᵥ) and a horizontal hole pitch (dₕ) of a 2G ReBCO HTS;

FIG. 10 and FIG. 11 show structures in which splicing of stabilizing layer and/or overlayer to stabilizing layer and/or overlayer can be performed;

FIG. 12 is a graph depicting current-voltage characteristics of a 2G ReBCO superconductors-spliced assembly using solid state atoms diffusion by pressurized splicing and oxygenation annealing according to one embodiment of the present invention; and

FIGS. 13 and 14 show magnetic field attenuation characteristics of a 2G ReBCO superconductors-spliced assembly using solid state atoms diffusion by pressurized splicing and oxygenation annealing according to one embodiment of the present invention, in which FIG. 13 is an image showing that a closed loop 2G ReBCO wire including a spliced zone is tested in liquid nitrogen, and FIG. 14 is a graph depicting results of magnetic field attenuation in a standby state, showing that the magnetic field is not attenuated at all even after 240 days once stabilized after magnetic flux creep.

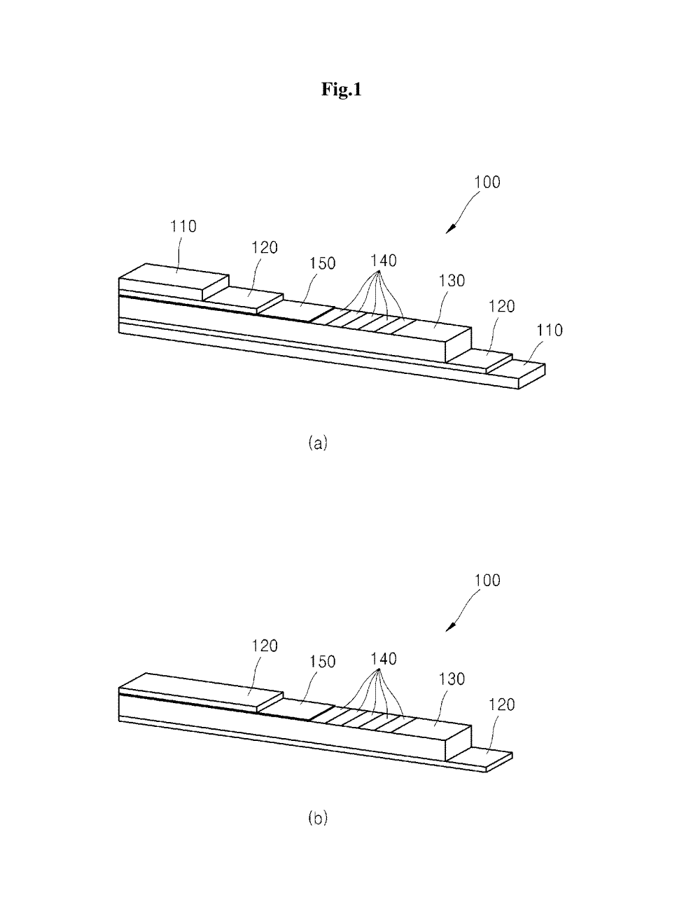

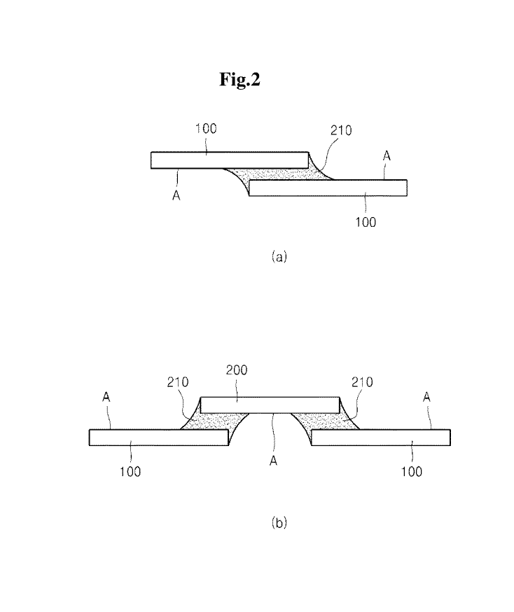

### DETAILED DESCRIPTION

Hereinafter, exemplary embodiments of the present invention will be described in detail with reference to the accompanying drawings.

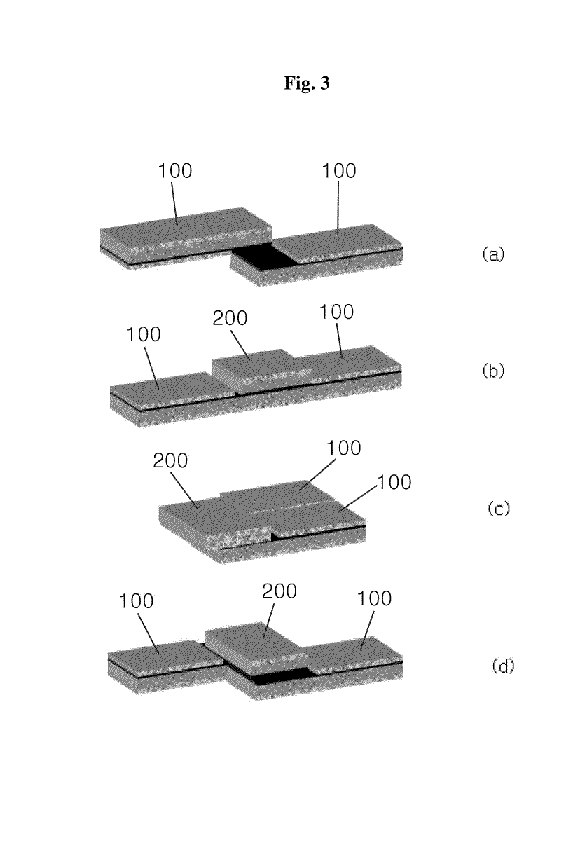

FIG. 3 is a schematic showing 4 kinds of splicing method of 2G ReBCO HTSs through direct contact of high temperature superconducting layers.

As in one example shown in FIG. 3 (a), two strands of 2G ReBCO HTSs 100 to be spliced may be disposed to face each other and directly spliced to each other (Lap joint splicing). In addition, as in examples shown in FIGS. 3 (b), (c) and (d), two strands of 2G ReBCO HTSs may be spliced to each other via a third 2G ReBCO HTS piece 200. In these examples, the 2G ReBCO HTSs may be spliced to each other via the third 2G ReBCO HTS piece 200 in various ways, for example, by splicing the third 2G ReBCO HTS piece 200 onto the two strands of 2G ReBCO HTSs 100 arranged linearly (bridge splicing) as shown in FIG. 3 (b), by splicing the third 2G ReBCO HTS piece 200 onto the two strands of 2G ReBCO HTSs 100 arranged in parallel (parallel bridge splicing) as shown in FIG. 3 (c), by splicing the third 2G ReBCO HTS piece 200 onto the two strands of 2G ReBCO HTSs 100 arranged in a zigzag shape to cross each other (stair bridge splicing) as shown in FIG. 3 (d), and the like.

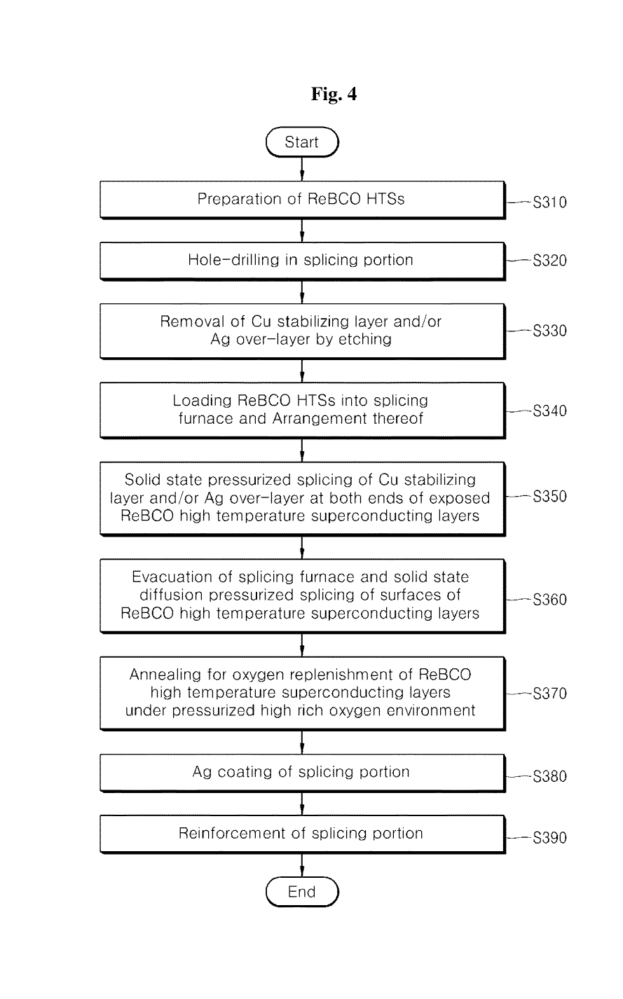

FIG. 4 is a schematic flow chart showing a method of splicing 2G ReBCO HTSs via solid state atoms diffusion by pressurized splicing through direct contact of high temperature superconducting layers, and for recovering lost superconductivity due to lost oxygen caused by out-diffusion of oxygen atoms during splicing at high temperature through oxygen supply via oxygen supply holes and oxygenation annealing for diffusion of the supplied oxygen into the superconducting layers according to one embodiment of the present invention.

Referring to FIG. 4, a method of splicing 2G ReBCO HTSs includes: preparing 2G ReBCO HTSs S310; drilling holes in a splicing portion for oxygen supply S320; removing a stabilizing layer and/or overlayer by etching S330; arranging the 2G ReBCO HTSs according to splicing type (lap or bridge) and placing the same in a splicing furnace S340; performing solid state pressurized splicing of copper (Cu) stabilizing layers and/or silver (Ag) overlayers at both ends of exposed 2G ReBCO high temperature superconducting layers S350; evacuating the splicing furnace and performing solid state atoms diffusion by pressurized splicing of the 2G ReBCO high temperature superconducting layers S360; annealing for oxygen replenishment to the 2G ReBCO high temperature superconducting layers S370; coating silver (Ag) S380; and reinforcing a spliced zone S390.

Preparation of ReBCO HTSs

First, in preparation of 2G ReBCO HTS CCs S310, 2G ReBCO HTS including a 2G ReBCO(ReBa₂Cu₃O₇₋ₓ, wherein Re is a rare-earth material, and x ranges from 0≦x≦0.6) superconducting layer and other layers are prepared.

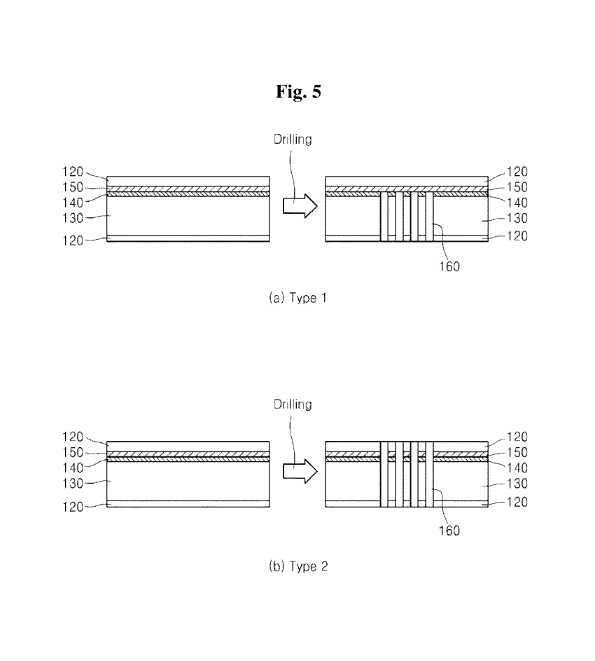

FIG. 5 shows examples of a hole-drilling process of a splicing portion between 2G ReBCO HTSs described below. FIG. 5(a) shows one example of hole-drilling in which holes are formed through a bottom to just below a superconductor layer, and FIG. 5 (b) shows another example of hole-drilling in which holes are formed through a 2G ReBCO HTS from a bottom to a copper (Cu) and/or a silver (Ag) layer. These examples will be referred to in description of the structure of a 2G ReBCO HTS.

Referring to FIG. 5, a 2G ReBCO HTS 100 includes a Ag overlayer 120, substrate 130, buffer layers 140, 2G ReBCO high temperature superconducting layer 150, and another Ag overlayer 120 from the bottom.

The layers are generally fabricated by an automated and continuous process using thin film deposition techniques. The layer 120 is formed of a Ag and substrate 130 may be formed of a metallic material such as Hastelloy.

The buffer layer 140 may be formed of a material including at least one selected from ZrO₂, CeO₂, yttria-stabilized zirconia (YSZ), Y₂O₃, HfO₂, MgO, LaMnO₃ (LMO), and the like. The buffer layer may be formed as a single layer or multiple layers on the substrate 130 through epitaxial lamination.

The ReBCO high temperature superconducting layer 150 is composed of a superconductive ReBCO (ReBa₂Cu₃O₇₋ₓ, wherein Re is a rare-earth material, and x ranges from 0≦x≦0.6). That is, advantageously, the molar ratio of Re:Ba:Cu is 1:2:3, and the molar ratio (7−x) of oxygen to the rare earth material is 6.4 or more. In ReBCO, if the molar ratio of oxygen to 1 mole of rare-earth material is less than 6.4, ReBCO may lose superconductivity, acting only as a normal conductor.

Among materials included in ReBCO, one example of the rare-earth material (Re) is yttrium (Y). Additionally, Nd, Gd, Eu, Sm, Er, Yb, Tb, Dy, Ho, Tm, and the like may be used as the rare-earth material.

The stabilizing layer 110 and/or the overlayer 120 is stacked on an upper surface of the ReBCO high temperature superconducting layer 150 to provide electrical stabilization to the superconducting layer 150 by protecting the superconducting layer 150 from over-current, and the like. The stabilizing layer 110 and/or the overlayer 120 is formed of a metallic material having relatively low electric resistance to protect the ReBCO high temperature superconducting layer 150 in the event of over-current. For example, the stabilizing layer 110 and/or overlayer 120 may be formed of a metallic material with relatively low electrical resistance such as copper (Cu) or silver (Ag), respectively. In some embodiments, the stabilizing layer may be formed of stainless steel.

Hole-Drilling in Splicing Portion

Next, in hole-drilling in a splicing portion S320, micro-holes 160 are formed in a portion of each of the 2G ReBCO HTSs to be connected to each other, that is, in a splicing portion. Micro-hole-drilling may be carried out via ultra-precision machining, laser machining, or the like.

Micro-holes 160 provide oxygen diffusion paths to the 2G ReBCO high temperature superconducting layer 150 in an annealing stage for oxygen replenishment to 2G ReBCO S370 so as to improve annealing efficiency, thereby allowing superconductors to maintain superconductivity while reducing annealing time.

Hole-drilling may be performed to penetrate the layers 110˜140 of the 2G ReBCO HTS CCs to just below the superconducting layer 150 (FIG. 5, Type I), or may be performed to penetrate the entire layers of the 2G ReBCO HTS CCs (FIG. 5, Type II).

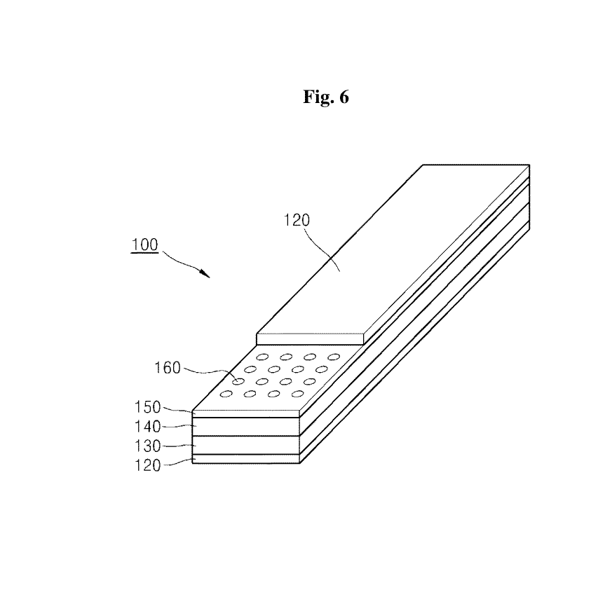

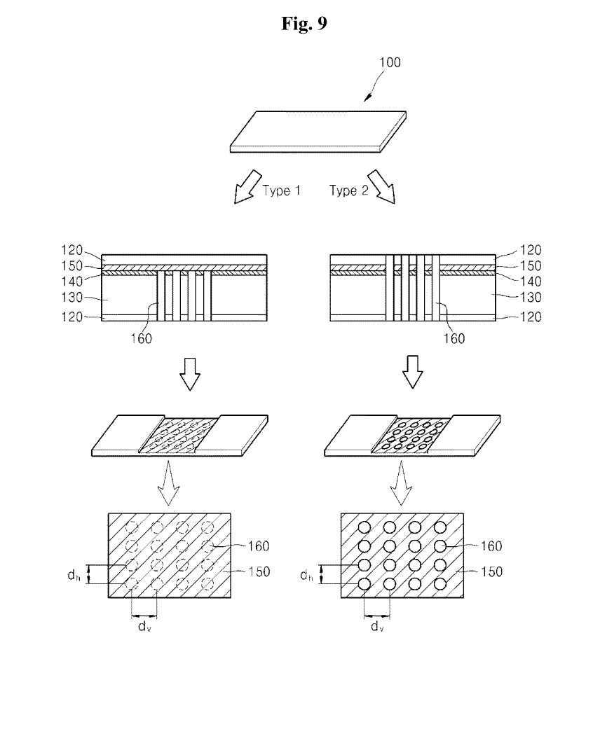

FIG. 6 shows a surface of the superconducting layer after hole-drilling FIG. 9 shows one example of hole-drilling, in which hole pitches are represented by vertical hole pitch×horizontal hole pitch (dᵥ×dₕ).

In FIG. 9, a left view shows Type I in which hole-drilling in the splicing portion is performed such that holes penetrate the layers 110˜140 to just below a superconducting layer 150 of the 2G ReBCO HTS, and a right view shows Type II in which hole-drilling in the splicing portion is performed such that holes are formed to penetrate the entire layers of 2G ReBCO HTS CCs.

Experimental results showed that both Type I and Type II superconductors clearly exhibit substantially the same current-voltage characteristics as those of virgin ReBCO, in which holes are not formed. In particular, the Type I superconductor having the holes formed through the substrate to just below the superconductor layer exhibits current-voltage characteristics more similar to those of the original 2G ReBCO HTS CCs.

In addition, from results of experiments in which the vertical hole pitch dᵥ and the horizontal hole pitch dₕ were variously set to, for example, 200 μm×200 μm, 400 μm×400 μm, 500 μm×500 μm, and the like, the current-voltage characteristics were improved with increasing pitch between micro-holes 160. Particularly, when the pitch between the micro-holes was 500 μm, the superconductor exhibited superior current-voltage characteristics to the other cases.

Removal of Stabilizing Layer and/or Overlayer Through Etching

Next, in removal of the stabilizing layer and/or overlayer through etching S330, the 2G ReBCO high temperature superconducting layer is exposed by etching the Copper (Cu) stabilizing layer and/or the Silver (Ag) overlayer of the 2G ReBCO HTS CCs.

In the 2G ReBCO HTS CCs, since 2G ReBCO is placed therein, the stabilizing layer and/or overlayer is removed by etching to expose the 2G ReBCO high temperature superconducting layer thereof in order to splice the 2G ReBCO high temperature superconducting layers through direct contact between.

When etching the stabilizing layer and/or overlayer, a resist having selective etching capability with respect to the stabilizing layer and/or over-layer or a resist having opposite etching capability may be used.

From the results of observation as to the current characteristics of the 2G ReBCO CCs when hole-drilling was performed before and after etching, it could be seen that, when hole-drilling was performed before etching for removal of the stabilizing layer and/or overlayer, the 2G ReBCO superconductor exhibited superior current characteristics than the current characteristics of the 2G ReBCO superconductor when hole-drilling was performed after etching for removal of the stabilizing layer and/or overlayer under the same conditions. Thus, hole-drilling is preferably performed before removal of the stabilizing and/or overlayers.

In addition, from results obtained by observing surface states when hole-drilling was performed using a laser before and after removal of the Copper (Cu) and/or Silver (Ag) layer, it could be seen that the surface was clearer when hole-drilling was performed using a laser after removal of the Copper (Cu) and/or Silver (Ag) layer.

Arrangement of ReBCO HTSs Depending on Splicing Type (Lap or Bridge) and Placing ReBCO HTSs into Splicing Furnace

In operation S340, the splicing-target 2G ReBCO HTSs are loaded into the splicing furnace, and arranged in a predetermined manner. Of course, the 2G ReBCO HTSs may be arranged before they are loaded into the splicing furnace.

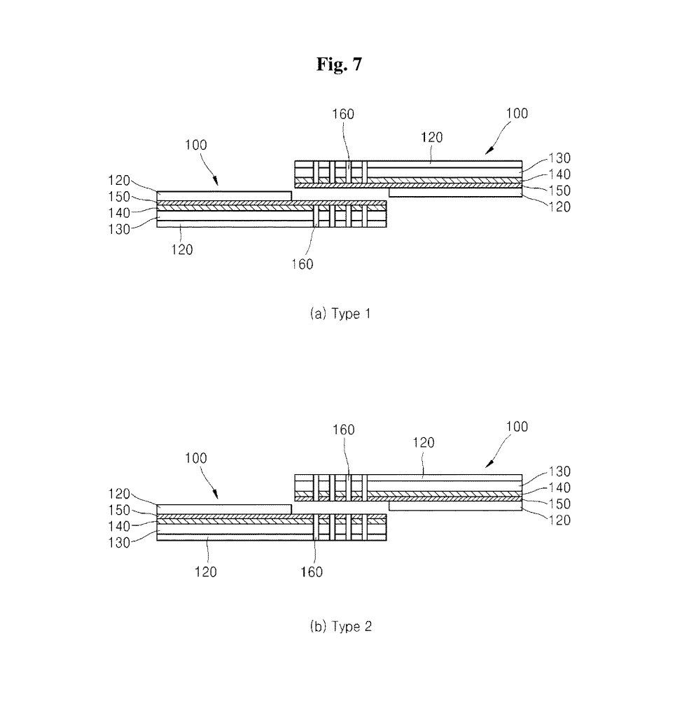

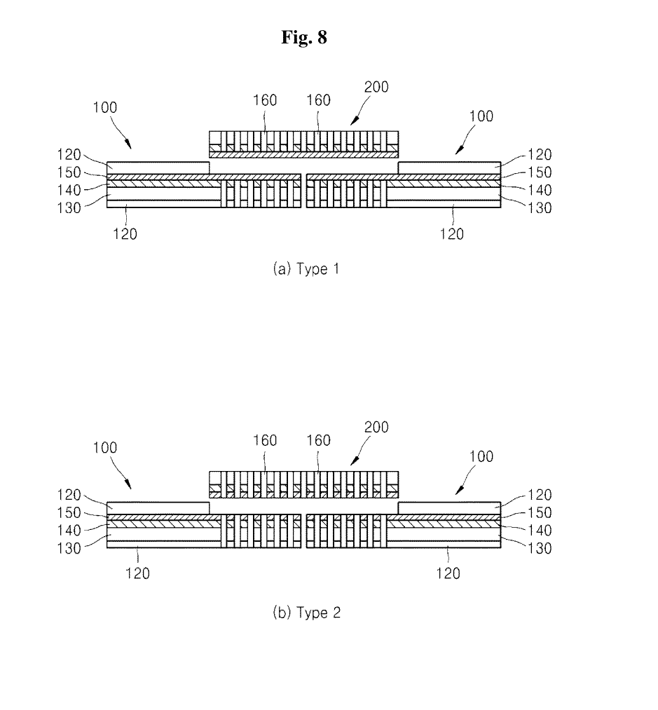

According to splicing type, the 2G ReBCO HTSs may be arranged in a lap joint manner (FIG. 7), or in a bridge joint in which two strands of the superconductor CCs are disposed in a bridge arrangement (butt type arrangement and a third superconductor CC piece is disposed to overlap the two semiconductor CCs) (FIG. 8). FIG. 7 and FIG. 8 show the 2G HTS CCs after forming holes therein.

FIG. 7 (a) and FIG. 8 (a) show Type I in which hole-drilling is performed through the layers 110˜140 of the 2G ReBCO HTS to just below the superconducting layer 150, and FIG. 7 (b) and FIG. 8 (b) show Type II in which hole-drilling is performed from the entire layers of the 2G ReBCO HTS CCs.

Solid State Pressurized Splicing of Copper (Cu) Stabilizing Layer and/or Silver (Ag) Overlayer

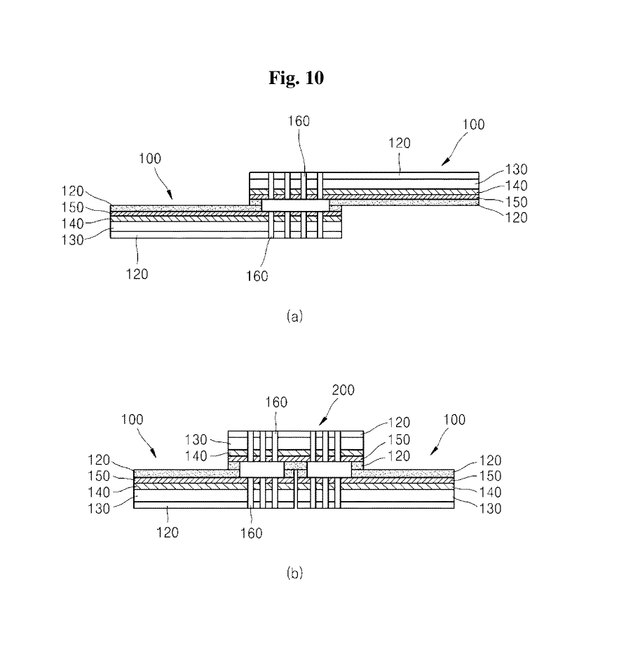

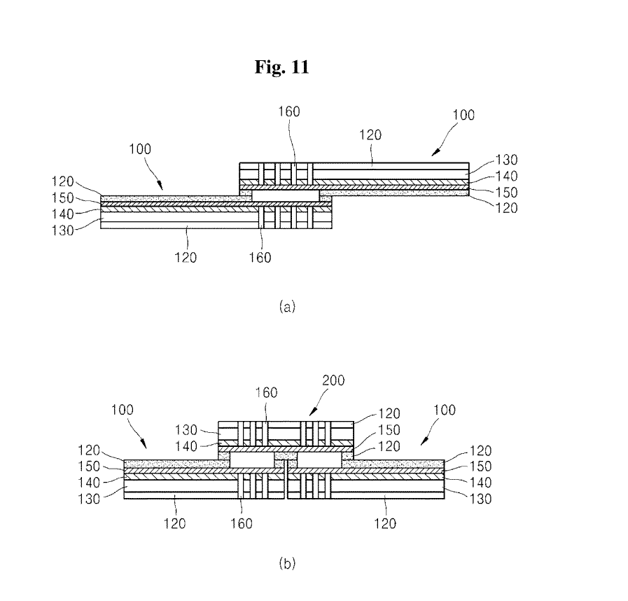

Referring to FIG. 10 and FIG. 11, in operation S350, before the 2G ReBCO high temperature superconducting layer of one strand of the ReBCO HTS is spliced to the 2G ReBCO high temperature superconducting layer of the other strand of the 2G ReBCO HTS CCs, the Copper (Cu) stabilizing layer and/or Silver (Ag) overlayer of the one strand of the 2G ReBCO HTS CCs and the Copper (Cu) stabilizing layer and/or Silver (Ag) overlayer of the other strand of the ReBCO HTS are directly spliced to each other. The Copper (Cu) stabilizing layers and/or Silver (Ag) overlayers may be directly spliced to each other by solid state pressurized splicing at atmospheric pressure in the splicing furnace.

The Copper (Cu) stabilizing layers and/or Silver (Ag) overlayers may have a direct splicing length from about 2 mm to about 3 mm, without being limited thereto.

Evacuation of Splicing Furnace and Solid State Atoms Diffusion Pressurized Splicing Between Surfaces of ReBCO High Temperature Superconducting Layers

In this operation S360, the splicing furnace is evacuated and solid state atoms diffusion by pressurized splicing with respect to the exposed surfaces of the 2G ReBCO high temperature superconducting layers of the 2G ReBCO HTS CCs is performed at a below peritectic reaction temperature of the ReBCO.

After solid state pressurized splicing of the Copper (Cu) stabilizing layers and/or Silver (Ag) overlayers, the splicing furnace is evacuated. Vacuum pressure may be set to PO₂≦10⁻⁵ mTorr. Evacuation of the splicing furnace to a vacuum is performed in order to allow only the 2G ReBCO high temperature superconducting layers of the 2G ReBCO HTSs to be spliced to each other through solid state atoms diffusion by pressurized splicing. When oxygen partial pressure is extremely low, silver (Ag) constituting the overlayer has a higher melting point than 2G ReBCO constituting the superconducting layer, thereby allowing solid state atoms diffusion of ReBCO without melting and contamination of silver (Ag).

In this case, a 2G ReBCO high temperature superconductors-spliced assembly, such as shown in the examples of FIG. 10 and FIG. 11, can be formed.

FIG. 10 and FIG. 11 show examples of 2G HTS CC assemblies of the Copper (Cu) stabilizing layers and/or Ag overlayer and Copper (Cu) stabilizing layers and/or the Ag overlayer.

After evacuation of the splicing furnace, with two exposed 2G ReBCO high temperature superconducting layers (in lap joint splicing) or three exposed 2G ReBCO high temperature superconducting layers (in bridge joint splicing with butt type arrangement using a third 2G ReBCO high temperature superconductor piece) contacting each other, the splicing furnace is heated to a predetermined temperature, that is, a below ReBCO peritectic reaction temperature to perform solid state atoms diffusion by pressurized splicing of the 2G ReBCO superconducting layers.

The furnace may be any type of furnace, such as a direct contact heating furnace, an induction heating furnace, a microwave heating furnace, or other heating furnace types.

When the furnace is a direct heating type furnace, a ceramic heater may be used. In this case, heat is directly transferred from the ceramic heater to the 2G ReBCO HTS CCs.

On the contrary, when the furnace is an indirect heating type furnace, an induction heater may be used. In this case, the 2G ReBCO HTS CCs may be heated through non-contact heating. In addition, the 2G ReBCO HTS CCs may be heated in a non-contact manner using microwaves.

The ReBCO peritectic reaction is as follows:

ReBa₂Cu₃O₇₋ₓ (Re123)→Re123+(BaCuO₂+CuO)+L (Re, Ba, Cu, O)→Re123+Re₂Ba₁Cu₁O₇₋ₓ (Re211)+L (Re, Ba, Cu, O)→Re211+L (Re, Ba, Cu, O). Here, L is liquid state.

Upon peritectic reaction of ReBCO, BaCuO₂ and CuO are generated and inhibit superconductivity. Thus, according to the invention, solid state atoms diffusion by pressurized splicing is performed at a temperature less than the temperature at which BaCuO₂ and CuO are generated.

Here, pressure may be additionally applied to the 2G ReBCO HTSs to promote face-to-face contact between the two superconducting layers and to accelerate atoms diffusion, and also to remove various defects such as lack of fusion, and the like, from the splicing portion while increasing a contact and joining area.

Advantageously, the splicing furnace has an inner temperature ranging from 400° C. or more to the just below ReBCO peritectic reaction temperature depending on the pressurization. If the inner temperature of the splicing furnace is less than 400° C., undesirable splicing can be encountered. On the contrary, if the inner temperature of the splicing furnace exceeds the ReBCO peritectic reaction temperature, liquid phase ReBCO is generated together with detrimental BaCuO₂ and CuO compounds.

Pressurization may be performed using a weight or an air cylinder. Applied pressure may range from 0.1 MPa to 30 MPa. If the applied pressure is less than 0.1 MPa, pressurization is insufficient. Conversely, if the applied pressure exceeds 30 MPa, there can be a problem of deterioration in stability of the 2G ReBCO HTSs.

In the method of the present invention, since the ReBCO superconducting layers of the 2G ReBCO HTSs are brought into direct contact with each other and subjected to solid state atoms diffusion by pressurized splicing, a normal conduction layer such as a solder or a filler is not present between the 2G ReBCO HTSs, thereby preventing generation of Joule heat or quenching due to joint resistance in the spliced zone.

Splicing of the 2G ReBCO HTSs may be carried out by lap joint splicing as shown in FIG. 7, or by bridge joint splicing with butt type arrangement as shown in FIG. 8.

In lap joint splicing, as shown in FIG. 7, with splicing surfaces of two 2G ReBCO HTSs 100 to be spliced, that is, exposed surfaces of the 2G ReBCO high temperature superconducting layers, disposed to face each other, the 2G ReBCO high temperature superconducting layers are directly subjected to solid state atoms diffusion pressurized splicing.

On the contrary, in bridge joint splicing with butt type arrangement, as shown in FIG. 8, distal ends of two 2G ReBCO superconducting layers 100 to be spliced are brought into contact in butt arrangement or separated a pre-determined distance from each other.

In this state, a separate small piece of ReBCO HTS (third ReBCO superconductor) 200, from which a stabilizing layer and/or overlayer is removed, is placed on the target 2G ReBCO HTSs 100. Then, solid state atoms diffusion by pressurized splicing is performed with respect to the three 2G ReBCO high temperature superconducting layers while compressing the splicing portions of the 2G ReBCO high temperature superconducting layers by applying a load thereto.

In lap joint splicing, the 2G ReBCO superconducting layer of one 2G ReBCO HTS adjoins the 2G ReBCO superconducting layer of the other 2G ReBCO HTS in lap arrangement.

On the other hand, for solid state atoms diffusion by pressurized splicing of ReBCO, the interior of the splicing furnace is preferably designed to permit adjustment of the partial pressure of oxygen (PO₂) within various ranges under vacuum.

Annealing for Replenishment of Oxygen to ReBCO High Temperature Superconducting Layer and Superconductivity Recovery

In this operation S370, the spliced zone of the 2G ReBCO high temperature superconducting layers is subjected to annealing under an oxygen atmosphere to supply oxygen to the 2G ReBCO high temperature superconducting layers.

Solid state atoms diffusion by pressurized splicing S360 is performed in a vacuum at a high temperature (400° C. or more). However, in such vacuum and high temperature conditions, oxygen (O2) escapes from the 2G ReBCO superconducting layers.

As oxygen escapes from the 2G ReBCO, the molar ratio of oxygen to 1 mole of the rare-earth material can be decreased below 6.4. In this case, the 2G ReBCO high temperature superconducting layer 150 may undergo atomic structure change from an orthorhombic structure of a superconductor to a tetragonal structure of a normal conductor, thus losing superconductivity.

To solve such a problem, in this annealing operation S370, while pressurizing at 200° C. to 700° C., annealing is performed under an oxygen atmosphere to compensate for lost oxygen in 2G ReBCO, thereby recovering superconductivity.

The oxygen atmosphere may be created by continuously supplying oxygen to the splicing furnace while pressurizing the furnace. This process is referred to as oxygenation annealing. In particular, oxygenation annealing is performed in a range of 200° C. to 700° C., since this temperature range provides the most stable orthorhombic phase recovering superconductivity.

If a low pressure is applied to the spliced zone upon annealing, there can be a problem in oxygen supply, and if a high pressure is applied thereto, durability of the superconductor can be adversely affected by the high force. Thus, the annealing furnace may have a pressure of about 1˜30 atm during annealing.

Since annealing is performed for replenishment of oxygen lost by solid state atoms diffusion by pressurized splicing, annealing may be performed until the molar ratio of oxygen (O₂) to 1 mole of Re (rare-earth material) in ReBCO becomes 6.4 to 7.

According to the invention, the micro-holes 160 are formed in the 2G ReB CO HTS CCs by hole drilling in the splicing portion S320, thereby providing a path for diffusion of oxygen into the 2G ReBCO high temperature superconducting layers during annealing. As a result, an annealing time for superconductivity recovery of the 2G ReBCO HTS CCs can be shortened.

As described above, in the solid state atoms diffusion by pressurized splicing method of the 2G ReBCO HTSs according to the invention, the micro-holes are pre-formed in the splicing portion before splicing of the 2G ReBCO HTSs to provide the diffusion path of oxygen into the 2G ReBCO high temperature superconducting layer during annealing, thereby shortening annealing time while maintaining superconductivity after splicing.

Silver (Ag) Coating of Spliced Zone of 2G ReBCO HTSs

After solid state atoms diffusion by pressurized splicing of the 2G ReBCO HTSs, the splicing zone does not include the copper (Cu) and/or silver (Ag) layer. Thus, when over-current flows to the spliced zone, the over-current does not bypass the spliced zone, thereby causing quenching.

To prevent such a problem, in operation S380, silver (Ag) coating is performed on the spliced zone of the 2G ReBCO HTSs and surroundings thereof.

Advantageously, silver (Ag) coating is performed to a thickness of 2 μm to 40 μm. If the thickness of the silver (Ag) coating layer is less than 2 μm, over-current bypassing becomes insufficient even after silver (Ag) coating. On the contrary, if the thickness of the silver (Ag) coating layer exceeds 40 μm, splicing cost increases without additional effects.

Reinforcement of Spliced Zone of 2G ReBCO HTSs

After silver (Ag) coating the spliced zone of the 2G ReBCO HTSs, in operation S390, the spliced zone of the 2G ReBCO HTSs is reinforced using a solder or an epoxy in order to protect the spliced zone from external stress.

As described above, the method according to the present invention employs solid state atoms diffusion pressurized splicing of 2G ReBCO high temperature superconducting layers through direct contact there between, and includes hole-drilling in a splicing portion of the 2G ReBCO HTSs, thereby improving splicing efficiency while ensuring superconductivity after splicing.

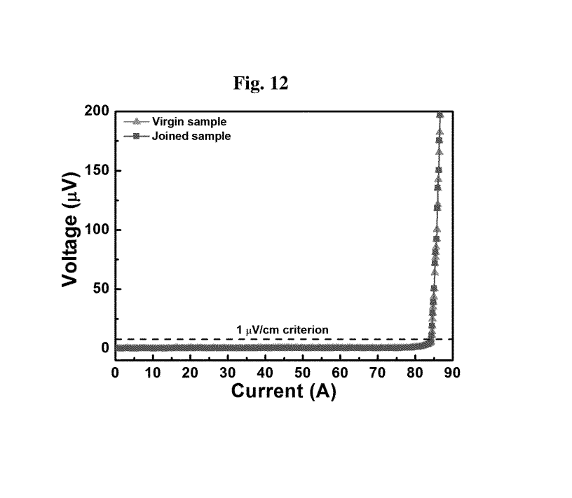

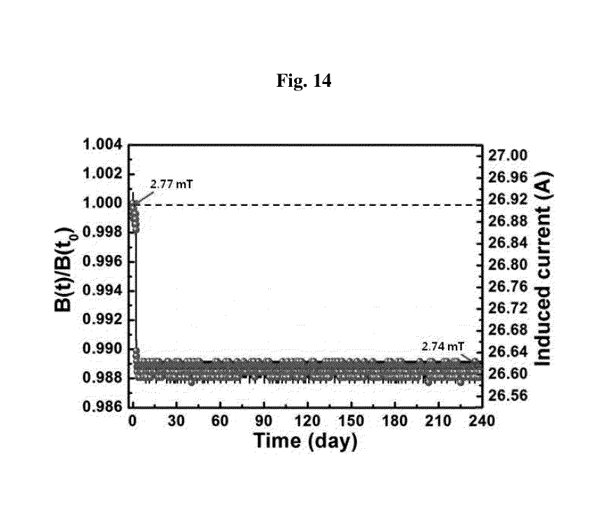

FIGS. 12 and 14 show current-voltage characteristics and magnetic field attenuation characteristics of superconductors-spliced assembly via solid state atoms diffusion by pressurized splicing and oxygenation annealing according to embodiments of the present invention.

Referring to FIG. 12, it can be seen that superconductor critical current (Ic) characteristics are 100% recovered.

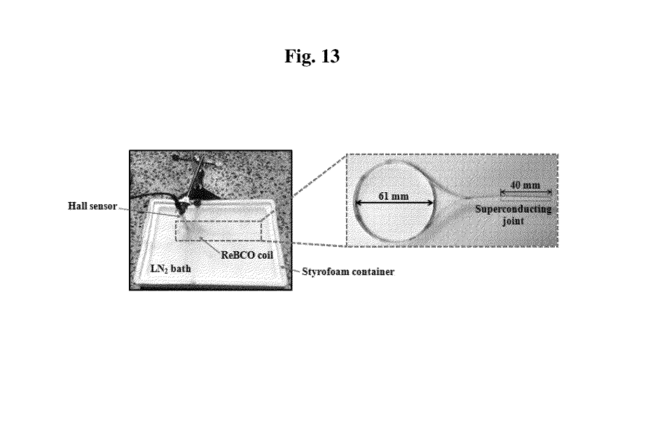

FIG. 13 shows that a closed loop 2G ReBCO wire including a spliced zone is tested in liquid nitrogen under magnetic field conditions.

In magnetic field attenuation testing, an Nd—Fe—B permanent magnet was inserted into a closed loop of the 2G ReBCO wire, both ends of which were spliced to each other, to excite a magnetic field in the 2G ReBCO wire, thereby imparting superconductivity. Then, the Nd—Fe—B permanent magnet was removed, and a Hall sensor was placed in the closed loop, thereby measuring magnetic field attenuation.

Magnetic field attenuation was evaluated according to the following Equation:

$$B ( t ) = B ( {t}_{0} ) {e}^{- ( \frac{{R}_{joint}}{L} ) t}$$

B(t): Induced magnetic field at time t (Tesla)

B(t₀): Initial magnetic field (Tesla)

Rⱼₒᵢₙₜ: Joint resistance (Ω)

L: Magnetic inductance of closed loop (Henry)

t: Time (Sec)

FIG. 14 is a graph depicting results of magnetic field attenuation. The initially induced magnetic field decays rapidly from 2.77 mT and reaches 2.74 mT for 120 seconds after the current is induced by a field-cooling process. The initial field decay settles down to 2.74 mT, which corresponds to a superconducting current of 26.61 A, and subsequently remains steady for 240 days. The initial decay of magnetic field may occur because the superconducting current induced by field-cooling exceeds the capability of the superconducting layer and flows through the Ag stabilizers. The total circuit resistance at L=3.44 μH is calculated using the above equation as <10⁻¹⁷Ω, which demonstrates that the model coil containing the superconducting joint operates in PCM.

Although some embodiments have been disclosed herein, it should be understood by those skilled in the art that these embodiments are not to be in any way construed as limiting the present invention, and that various modifications, changes, and alterations can be made without departing from the spirit and scope of the invention. Therefore, the scope of the invention should be limited only by the accompanying claims and equivalents thereof.

What is claimed is:

1. A method of splicing second generation ReBCO high temperature superconductors (2G ReBCO HTSs), comprising:
(a) preparing, as splicing targets, two strands of 2G ReBCO HTSs each including a ReBCO high temperature superconducting layer (ReBa₂Cu₃O₇₋ₓ, wherein Re is a rare-earth material, and x ranges from 0≦x≦0.6) and other layers;
(b) drilling holes in a splicing portion of each of the 2G ReBCO HTSs;
(c) etching the splicing portion of each of the 2G ReBCO HTSs to remove the Copper (Cu) and/or Silver (Ag) layer from and expose the ReBCO high temperature superconducting layers at the splicing portion;
(d) loading the 2G ReBCO HTSs into a splicing furnace, and arranging the 2G ReBCO HTSs such that the exposed surfaces of the two 2G ReBCO HTSs directly abut, or such that the two exposed surfaces of the 2G ReBCO high temperature superconducting layers directly abut an exposed surface of a 2G ReBCO high temperature superconducting layer of a third 2G ReBCO HTS;
(e) performing solid state pressurized splicing of the Copper (Cu) stabilizing layer and/or Silver (Ag) overlayer at both ends of the exposed surfaces of the ReBCO high temperature superconducting layers at atmospheric pressure in the splicing furnace to increase bonding strength of the entire 2G HTSs;
(f) performing solid state atoms diffusion by pressurized splicing of the exposed surfaces of the 2G ReBCO high temperature superconducting layers of the 2G ReBCO HTSs by evacuating the splicing furnace and heating the splicing furnace to a below ReBCO peritectic reaction temperature;
(g) annealing a spliced zone between the 2G ReBCO HTSs under oxygen atmosphere to supply oxygen to the 2G ReBCO high temperature superconducting layer in each of the 2G ReBCO HTS CCs;
(h) coating the spliced zone between the 2G ReBCO HTS CCs with silver (Ag) so as to prevent quenching by bypassing over-current at the spliced zone; and
(i) reinforcing the spliced zone between the 2G ReBCO HTS CCs with solder or epoxy.

2. The method according to claim 1, wherein the (b) drilling holes in a splicing portion comprise forming holes penetrating the substrate to just below the superconductor layer, or from the substrate to the stabilizing layer, the respective holes having a diameter of 10 μm to 100 μm and being arranged at a pitch of 1 μm to 1000 μm.

3. The method according to claim 1, wherein the (c) etching the 2G ReBCO HTSs is performed by wet etching or plasma dry etching.

4. The method according to claim 1, wherein the (e) performing solid state pressurized splicing is performed at a splicing temperature from 400° C. or more to a below ReBCO peritectic reaction temperature while applying pressure to the splicing portion of the HTSs at a load from 0.1 MPa to 30 MPa.

5. The method according to claim 1, wherein in the (f) performing atoms diffusion by pressurized splicing the spliced zone of the 2G ReBCO HTS CCs is compressed by an external load while being heated.

6. The method according to claim 1, wherein the (g) annealing a spliced zone comprises supplying oxygen gas to the splicing furnace under a pressurized high rich pure oxygen atmosphere at a temperature of 200° C. to 700° C. until the 2G ReBCO has 6.4 to 7 moles of oxygen with respect to 1 mole of Re (rare-earth material) in 2G ReBCO.

7. The method according to claim 1, wherein the (h) the spliced zone comprises coating silver (Ag) to a thickness of 2 μm to 40 μm on the spliced zone to improve over-current bypass efficiency.

8. A 2G ReBCO HTSs-spliced assembly, in which a 2G ReBCO high temperature superconducting layer of one strand of a 2G ReBCO HTS is spliced to a 2G ReBCO high temperature superconducting layer of another strand of a 2G ReBCO HTS, wherein, at both sides of a spliced zone between the high temperature superconducting layers, a stabilizing layer and/or overlayer of the one strand of the 2G ReBCO HTS is also directly spliced to a stabilizing layer and/or overlayer of the other strand of the ReBCO HTS to increase bonding strength of the entire 2G HTS CCs.

9. The 2G ReBCO HTSs-spliced assembly according to claim 8, wherein each of the 2G ReBCO HTSs comprises:
a substrate;
a buffer layer formed as at least one layer on the substrate;
a 2G ReBCO high temperature superconducting layer formed on the buffer layer;
Silver (Ag) overlayers formed on the 2G ReBCO high temperature superconducting layer and on the substrate, respectively, the Ag overlayers electrically stabilizing the 2G ReBCO high temperature superconducting layer; and
Copper (Cu) stabilizers formed on each of the Ag overlayers.

10. The 2G ReBCO HTSs-spliced assembly according to claim 8, wherein each of the 2G ReBCO HTSs comprises:
a substrate;
a buffer layer formed as at least one layer on the substrate;
a 2G ReBCO high temperature superconducting layer formed on the buffer layer; and
Silver (Ag) overlayers formed on the 2G ReBCO high temperature superconducting layer and on the substrate, respectively, the Ag overlayers electrically stabilizing the 2G ReBCO high temperature superconducting layer.
